(19) United States
(12) Patent Application Publication
(10) Pub. No.: US 2026/0343968 A1
(43) Pub. Date: Oct. 29, 2026

(54) HIGH VOLTAGE SEMICONDUCTOR DEVICE

(71) Applicant: UNITED MICROELECTRONICS CORP., Hsin-Chu City (TW)

(72) Inventors: Yu-Hung Chang, Tainan City (TW); Ling-Chun Chou, Tainan City (TW); Te-Chi Yen, Tainan City (TW); Pin-Tseng Chen, Kaohsiung City (TW); Kun-Hsien Lee, Tainan City (TW)

(73) Assignee: UNITED MICROELECTRONICS CORP., Hsin-Chu City (TW)

(21) Appl. No.: 19/216,700

(22) Filed: May 22, 2025

(30) Foreign Application Priority Data
Apr. 25, 2025 (TW) 114115648

(51) Int. Cl. H10D 62/10; H10D 30/01; H10D 30/65

(52) U.S. Cl. CPC H10D 62/124; H10D 30/65; H10D 62/102; H10D 62/115; H10D 30/0281

(57) ABSTRACT

A high voltage semiconductor device includes a semiconductor substrate, a p-type drift region, an n-type doped region, and an isolation structure. The p-type drift region is disposed in the semiconductor substrate. The n-type doped region is disposed in the p-type drift region, and a bottom of the n-type doped region is connected with a bottom of the p-type drift region. At least a part of the isolation structure is disposed in the n-type doped region. The p-type drift region comprises a first lateral face, and the n-type doped region comprises a second lateral face located between the first lateral face and the isolation structure in a horizontal direction. A distance between the second lateral face and the isolation structure in the horizontal direction is less than a distance between the first lateral face and the isolation structure in the horizontal direction.

### BACKGROUND OF THE INVENTION

### 1. Field of the Invention

The present invention relates to a high voltage semiconductor device, and more particularly, to a high voltage semiconductor device including a p-type drift region and an n-type doped region.

### 2. Description of the Prior Art

Double-diffused MOS (DMOS) transistor devices have drawn much attention in power devices having high voltage capability. The conventional DMOS transistor devices are categorized into vertical double-diffused MOS (VDMOS) transistor device and lateral double-diffused MOS (LDMOS) transistor device. Having advantage of higher operational bandwidth, higher operational efficiency, and convenience to be integrated with other integrated circuit due to its planar structure, LDMOS transistor devices are prevalently used in high operation voltage environment such as CPU power supply, power management system, AC/DC converter, and high-power or high frequency band power amplifier. The essential feature of LDMOS transistor device is a lateral-diffused drift region with low doping concentration and large area. The drift region is used to alleviate the high voltage between the drain and the source, and therefore LDMOS transistor device can have higher breakdown voltage. However, as the requirements of related products become higher and higher, how to improve the electrical performance, the voltage endurance and/or the reliability of high voltage semiconductor devices through design modifications in the structure and/or the manufacturing process is still a continuous issue for those in the relevant fields.

### SUMMARY OF THE INVENTION

A high voltage semiconductor device is provided in the present invention. An n-type doped region is disposed in a p-type drift region and the range of the n-type doped region is controlled for enhancing the electrical performance of the high voltage semiconductor device and reducing negative influence on the reliability.

According to an embodiment of the present invention, a high voltage semiconductor device is provided. The high voltage semiconductor device includes a semiconductor substrate, a p-type drift region, an n-type doped region, and an isolation structure. The p-type drift region is disposed in the semiconductor substrate, the n-type doped region is disposed in the p-type drift region, and a bottom of the n-type doped region is connected with a bottom of the p-type drift region. At least a part of the isolation structure is disposed in the n-type doped region, the p-type drift region includes a first lateral face, and the n-type doped region includes a second lateral face located between the first lateral face and the isolation structure in a horizontal direction. A distance between the second lateral face and the isolation structure in the horizontal direction is less than a distance between the first lateral face and the isolation structure in the horizontal direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The patent or application file contains at least one drawing executed in color. Copies of this patent or patent application publication with color drawings will be provided by the Office upon request and payment of the necessary fee.

FIG. 1 is a schematic drawing illustrating a high voltage semiconductor device according to a first embodiment of the present invention.

FIG. 2 is a flow chart of a part of a manufacturing method of a high voltage semiconductor device according to an embodiment of the present invention.

FIGS. 3-5 are schematic drawings illustrating a manufacturing method of a high voltage semiconductor device according to an embodiment of the present invention, wherein FIG. 4 is a schematic drawing in a step subsequent to FIG. 3, and FIG. 5 is a schematic drawing in a step subsequent to FIG. 4.

FIG. 6 is a schematic drawing illustrating a high voltage semiconductor device according to a second embodiment of the present invention.

FIG. 7 is a schematic drawing illustrating distribution of impact ionization in the high voltage semiconductor device according to the second embodiment of the present invention.

FIG. 8 is a schematic drawing illustrating distribution of impact ionization in the high voltage semiconductor device according to the first embodiment of the present invention.

FIG. 9 is a schematic drawing illustrating current distribution in the high voltage semiconductor device according to the second embodiment of the present invention.

FIG. 10 is a schematic drawing illustrating current distribution in the high voltage semiconductor device according to the first embodiment of the present invention.

### DETAILED DESCRIPTION

The present invention has been particularly shown and described with respect to certain embodiments and specific features thereof for being realized by those skilled in the art. The embodiments set forth herein below are to be taken as illustrative rather than limiting. It should be readily apparent to those of ordinary skill in the art that various changes and modifications in form and detail may be made without departing from the spirit and the scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “forming” or the term “disposing” are used hereinafter to describe the behavior of applying a layer of material to the substrate or a doped region in the substrate. Such terms are intended to describe any possible layer or doped region forming techniques including, but not limited to, thermal growth, sputtering, evaporation, chemical vapor deposition, epitaxial growth, electroplating, ion implantation, and the like.

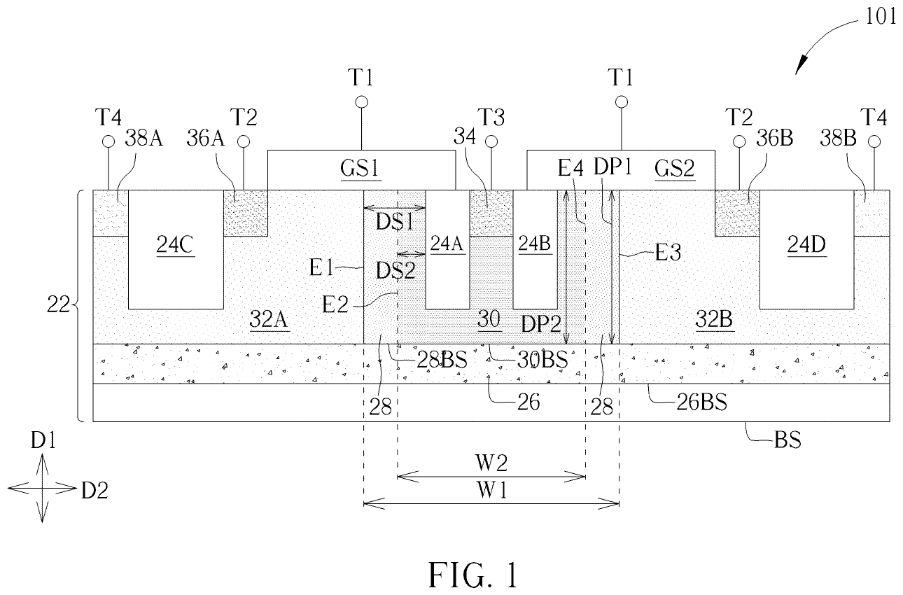

Please refer to FIG. 1. FIG. 1 is a schematic drawing illustrating a high voltage semiconductor device 101 according to a first embodiment of the present invention. As shown in FIG. 1, the high voltage semiconductor device 101 includes a semiconductor substrate 22, a p-type drift region 28, an n-type doped region 30, and an isolation structure 24A. The p-type drift region 28 is disposed in the semiconductor substrate 22, the n-type doped region 30 is disposed in the p-type drift region 28, and a bottom of the n-type doped region 30 (such as but not limited to a bottom surface 30BS) is directly connected with a bottom of the p-type drift region 28 (such as but not limited to a bottom surface 28BS). At least a part of the isolation structure 24A is disposed in the n-type doped region 30. The p-type drift region 28 includes a first lateral face (such as a lateral face E1), and the n-type doped region 30 includes a second lateral face (such as a lateral face E2) located between the lateral face E1 and the isolation structure 24A in a horizontal direction D2. A distance DS2 between the lateral face E2 and the isolation structure 24A in the horizontal direction D2 is less than a distance DS1 between the lateral face E1 and the isolation structure 24A in the horizontal direction D2. The electrical performance of the high voltage semiconductor device 101 may be improved (for example, the breakdown voltage of the high voltage semiconductor device 101 may be increased, but not limited thereto) and the negative influence on reliability may be reduced by disposing the n-type doped region 30 in the p-type drift region 28 and controlling the range of the n-type doped region 30.

In some embodiments, a vertical direction D1 may be regarded as a thickness direction of the semiconductor substrate 22, the semiconductor substrate 22 may have a top surface and a bottom surface BS opposite to the top surface in the vertical direction D1, and the p-type drift region 28 and the n-type doped region 30 described above may be located adjacent to the top surface. A horizontal direction substantially orthogonal to the vertical direction D1 (such as the horizontal direction D2 and other directions orthogonal to the vertical direction D1) may be substantially parallel with the top surface and/or the bottom surface BS of the semiconductor substrate 22, but not limited thereto. In this description, a distance between the bottom surface BS of the semiconductor substrate 22 and a relatively higher location and/or a relatively higher part in the vertical direction D1 may be greater than a distance between the bottom surface BS of the semiconductor substrate 22 and a relatively lower location and/or a relatively lower part in the vertical direction D1. The bottom or a lower portion of each component may be closer to the bottom surface BS of the semiconductor substrate 22 in the vertical direction D1 than the top or upper portion of this component. Another component disposed above a specific component may be regarded as being relatively far from the bottom surface BS of the semiconductor substrate 22 in the vertical direction D1, and another component disposed under a specific component may be regarded as being relatively close to the bottom surface BS of the semiconductor substrate 22 in the vertical direction D1. In this description, a top surface and a top portion of a specific component may include but is not limited to the topmost surface and the topmost portion of this component in the vertical direction D1, and a bottom surface and a bottom portion of a specific component may include but is not limited to the bottommost surface and the bottommost portion of this component in the vertical direction D1. In this description, the condition that a certain component is disposed between two other components in a specific direction may include but is not limited to a condition that the certain component is sandwiched between the two other components in the specific direction.

In some embodiments, the high voltage semiconductor device 101 may further include a deep n-type doped well region 26, a gate structure GS1, an n-type doped well region 32A, a first heavily p-type doped region (such as a heavily p-type doped region 34), a second heavily p-type doped region (such as a heavily p-type doped region 36A), a heavily n-type doped region 38A, and an isolation structure 24C. The deep n-type doped well region 26 and the n-type doped well region 32A are disposed in the semiconductor substrate 22, and the gate structure GS1 is disposed on the semiconductor substrate 22. A part of the n-type doped well region 32A and a part of the p-type drift region 28 are located at two opposite sides of the gate structure GS1 in the horizontal direction D2, respectively, and another part of the n-type doped well region 32A and another part of the p-type drift region 28 are located under the gate structure GS1 in the vertical direction D1. A part of the deep n-type doped well region 26 is located under the p-type drift region 28 and the n-type doped region 30 in the vertical direction D1, and another part of the deep n-type doped well region 26 is located under the n-type doped well region 32A in the vertical direction D1. The heavily p-type doped region 34 is disposed in the p-type drift region 28 and located in the n-type doped region 30, the heavily p-type doped region 36A is disposed in the n-type doped well region 32A, and the heavily p-type doped region 34 and the heavily p-type doped region 36A are located at two opposite sides of the gate structure GS1 in the horizontal direction D2, respectively. In some embodiments, the heavily p-type doped region 34 may be a drain doped region, the heavily p-type doped region 36A may be a source doped region, and the gate structure GS1, the p-type drift region 28, the n-type doped region 30, the n-type doped well region 32A, the heavily p-type doped region 34, the heavily p-type doped region 36A, and the deep n-type doped well region 26 may constitute a p-type lateral double-diffused metal oxide semiconductor (PLDMOS) transistor structure, but not limited thereto. In addition, the isolation structure 24C and the heavily n-type doped region38A may be disposed in the n-type doped well region 32A, at least a part of the heavily p-type doped region 36A may be located between the gate structure GS1 and the isolation structure 24C in the horizontal direction D2, and the heavily n-type doped region 38A and the heavily p-type doped region 36A may be located at two opposite sides of the isolation structure 24C in the horizontal direction D2, respectively.

In some embodiments, the gate structure GS1 may include a gate dielectric layer (not illustrated) and a gate electrode (not illustrated) disposed on the gate dielectric layer, the gate dielectric layer may include oxide dielectric material (such as silicon oxide, but not limited thereto), high dielectric constant (high-k) dielectric material, or other suitable dielectric materials, and the gate electrode may include non-metallic electrically conductive material (such as doped polysilicon) or metallic electrically conductive material, such as a metal gate including a work function layer and a low resistivity layer stacked with each other, but not limited thereto. The isolation structure 24A and the isolation structure 24C may include a single layer or multiple layers of insulation materials, such as oxide insulation material or other suitable insulation materials, and the isolation structure 24A and the isolation structure 24C may be regarded as trench isolation structures, but not limited thereto. In some embodiments, the semiconductor substrate 22 may include a silicon substrate, an epitaxial silicon substrate, a silicon germanium substrate, a silicon carbide substrate, a silicon-on-insulator (SOI) substrate, or a substrate made of other suitable semiconductor materials. The drift region, each of the doped regions, and each of the doped well regions described above may be formed by performing a suitable doping process (such as an implantation process or other doping approaches) to the semiconductor substrate 22. For example, some regions of the semiconductor substrate 22 may be doped with n-type dopants for forming the n-type doped region or the n-type doped well region, some regions of the semiconductor substrate 22 may be doped with p-type dopants for forming the p-type doped region, p-type doped well region, or the p-type drift region, and the doping dose for the heavily doped region may be relatively high, but not limited thereto.

The n-type dopants described above may include phosphorus (P), arsenic (As), or other suitable n-type doping materials, and the p-type dopants described above may include boron (B), gallium (Ga), or other suitable p-type doping materials. In some embodiments, the p-type drift region 28 may include p-type dopants (such as boron, but not limited thereto), the n-type doped region 30 may include n-type dopants (such as phosphorus, but not limited thereto) and a part of the p-type dopants of the p-type drift region 28. In other words, the n-type doped region 30 may be regarded as a region formed by performing counter doping to a portion of the p-type drift region 28, and the overall semiconductor characteristics of the n-type doped region 30 may be still p-type. Additionally, in some embodiments, the n-type doped region 30 and the n-type doped well region 32A may be formed concurrently by the same process and have the same n-type dopant. For example, the n-type doped region 30 may include first n-type dopants, the n-type doped well region 32A may include second n-type dopants, and each of the first n-type dopants is identical to each of the second n-type dopants (such as being phosphorus both, but not limited thereto).

In some embodiments, at least a part of the isolation structure 24A may be disposed under the gate structure GS1 in the vertical direction D1, and the lateral face E1 and the lateral face E2 may be located under gate structure GS1 in the vertical direction D1. The lateral face E2 of the n-type doped region 30 and the heavily p-type doped region 34 may be located at two opposite sides of the isolation structure 24A in the horizontal direction D2, respectively, and a part of the n-type doped region 30 and the heavily p-type doped region 34 may be located at the two opposite sides of the isolation structure 24A in the horizontal direction D2, respectively. The lateral face E1 of the p-type drift region 28 and the heavily p-type doped region 34 may be located at the two opposite sides of the isolation structure 24A in the horizontal direction D2, respectively, and a part of the p-type drift region 28 and the heavily p-type doped region 34 may be located at the two opposite sides of the isolation structure 24A in the horizontal direction D2, respectively. In addition, a part of the n-type doped region 30 may be located between the isolation structure 24A and the deep n-type doped well region 26 in the vertical direction D1, the n-type doped region 30 may be directly connected with the deep n-type doped well region 26 located under the n-type doped region 30 in the vertical direction D1, and the p-type drift region 28 may be directly connected with the deep n-type doped well region 26 located under the p-type drift region 28 in the vertical direction D1, but not limited thereto.

In some embodiments, the bottom surface 30BS of the n-type doped region 30 and the bottom surface 28BS of the p-type drift region 28 may be substantially coplanar, and the bottom surface 30BS and the bottom surface 28BS may be directly connected with the deep n-type doped well region 26, but not limited thereto. A depth DP2 of the n-type doped region 30 in the vertical direction D1 (may be regarded as a length of the n-type doped region 30 in the vertical direction D1 also) may be substantially equal to a depth DP1 of the p-type drift region 28 in the vertical direction D1 (may be regarded as a length of the p-type drift region 28 in the vertical direction D1 also), a length of the n-type doped region 30 in the horizontal direction D2 may be less than a length of the p-type drift region 28 in the horizontal direction D2, and the n-type doped region 30 is disposed in the p-type drift region 28 without being located outside the p-type drift region 28. In some embodiments, the p-type drift region 28 and the n-type doped region 30 may extend in another horizontal direction (such as another horizontal direction orthogonal to the horizontal direction D2, but not limited thereto), a width W1 of the p-type drift region 28 and a width W2 of the n-type doped region 30 may be regarded as a length of the p-type drift region 28 in the horizontal direction D2 and a length of the n-type doped region 30 in the horizontal direction D2, respectively, and the width W2 is less than the width W1. In some embodiments, the distance DS2 between the lateral face E2 and the isolation structure 24A in the horizontal direction D2 may be greater than or equal to 0.16 times the distance DS1 between the lateral face E1 and the isolation structure 24A in the horizontal direction D2, and the distance DS2 may be less than or equal to 0.5 times the distance DS1, but not limited thereto. For example, the distance DS1 may be about 0.3 micrometers, and the distance DS2 may range from 0.05 micrometers to 0.15 micrometers, but not limited thereto.

In some embodiments, the high voltage semiconductor device 101 may further include a gate structure GS2, an n-type doped well region 32B, a heavily p-type doped region 36B, a heavily n-type doped region 38B, an isolation structure 24B, and an isolation structure 24D. The n-type doped well region 32B, the heavily p-type doped region 36B, and the heavily n-type doped region 38B are disposed in the semiconductor substrate 22, and the gate structure GS2 is disposed on the semiconductor substrate 22. At least a part of the isolation structure 24B is disposed in the n-type doped region 30, and at least a part of the isolation structure 24D is disposed in the n-type doped well region 32B. The n-type doped well region 32A and the n-type doped well region 32B are located at two opposite sides of the p-type drift region 28 in the horizontal direction D2, respectively. The isolation structure 24A and the isolation structure 24B are located at two opposite sides of the heavily p-type doped region 34 in the horizontal direction D2, respectively. The gate structure GS1 and the gate structure GS2 are located at two opposite sides of the heavily p-type doped region 34 in the horizontal direction D2, respectively. A part of the n-type doped well region 32B and a part of the p-type drift region 28 are located at two opposite sides of the gate structure GS2 in the horizontal direction D2, respectively, and another part of the n-type doped well region 32B and another part of the p-type drift region 28 are located under the gate structure GS2 in the vertical direction D1. A part of the deep n-type doped well region 26 is located under the n-type doped well region 32B and directly connected with the n-type doped well region 32B. The heavily p-type doped region 36B is disposed in the n-type doped well region 32B, and the heavily p-type doped region 34 and the heavily p-type doped region 36B are disposed at two opposite sides of the gate structure GS2 in the horizontal direction D2, respectively. In addition, the isolation structure 24D and the heavily n-type doped region 38B may be disposed in the n-type doped well region 32B. At least a part of the heavily p-type doped region 36B may be located between the gate structure GS2 and the isolation structure 24D in the horizontal direction D2. The heavily n-type doped region 38B and the heavily p-type doped region 36B may be located at two opposite sides of the isolation structure 24D in the horizontal direction D2, respectively.

In some embodiments, the heavily p-type doped region 34 may be a drain doped region, the heavily p-type doped region 36B may be a source doped region, and the gate structure GS2, the p-type drift region 28, the n-type doped region 30, the n-type doped well region 32B, the heavily p-type doped region 34, the heavily p-type doped region 36B, and the deep n-type doped well region 26 may constitute another p-type lateral double-diffused metal oxide semiconductor (PLDMOS) transistor structure. The drain electrode (such as the heavily p-type doped region 34) may be shared by the PLDMOS transistor structure including the gate structure GS1 and the PLDMOS transistor structure including the gate structure GS2, but not limited thereto. In some embodiments, the gate structure GS1 and the gate structure GS2 may be electrically connected to a terminal T1, the heavily p-type doped region 36A and the heavily p-type doped region 36B may be electrically connected to a terminal T2, the heavily p-type doped region 34 may be electrically connected to a terminal T3, and the heavily n-type doped region 38A and the heavily n-type doped region 38B may be electrically connected to a terminal T4. The terminal T1 may include a gate electrode terminal, the terminal T2 may include a source electrode terminal, the terminal T3 may include a drain electrode terminal, and the terminal T4 may be used to adjust electric potential in the n-type doped well region 32A and the n-type doped well region 32B via the heavily n-type doped region 38A and the heavily n-type doped region 38B, respectively, but not limited thereto. The gate structure GS1 and the gate structure GS2 are separated from each other. The gate structure GS1 and the gate structure GS2 may be formed concurrently by the same process and have the same material composition accordingly; the isolation structure 24A, the isolation structure 24B, the isolation structure 24C, and the isolation structure 24D may be formed concurrently by the same process and have the same material composition accordingly; the n-type doped well region 32A and the n-type doped well region 32B may be formed concurrently by the same process and have the same material composition accordingly; and the heavily p-type doped region 36A and the heavily p-type doped region 36B may be formed concurrently by the same process and have the same material composition accordingly, but not limited thereto.

In some embodiments, the p-type drift region 28 may include the lateral face E1 and a third lateral face (such as a lateral face E3) opposite to the lateral face E1 in the horizontal direction D2, and the n-type doped region 30 may include the lateral face E2 and a fourth lateral face (such as a lateral face E4) opposite to the lateral face E2 in the horizontal direction D2. The lateral face E4 is located between the lateral face E3 and the isolation structure 24B in the horizontal direction D2, at least a part of the isolation structure 24B may be disposed under the gate structure GS2 in the vertical direction D1, and the lateral face E3 and the lateral face E4 may be located under the gate structure GS2 in the vertical direction D1. The lateral face E4 and the heavily p-type doped region 34 may be located at two opposite sides of the isolation structure 24B in the horizontal direction D2, respectively, and a part of the n-type doped region 30 and the heavily p-type doped region 34 may be located at the two opposite sides of the isolation structure 24B in the horizontal direction D2, respectively. The lateral face E3 and the heavily p-type doped region 34 may be located at the two opposite sides of the isolation structure 24B in the horizontal direction D2, respectively, and a part of the p-type drift region 28 and the heavily p-type doped region 34 may be located at the two opposite sides of the isolation structure 24B in the horizontal direction D2, respectively. The distance between the lateral face E4 and the isolation structure 24B in the horizontal direction D2 is less than the distance between the lateral face E3 and the isolation structure 24B in the horizontal direction D2. In some embodiments, the distance between the lateral face E4 and the isolation structure 24B in the horizontal direction D2 may be substantially equal to the distance DS2 described above, and the distance between the lateral face E3 and the isolation structure 24B in the horizontal direction D2 may be substantially equal to the distance DS1 described above, but not limited thereto.

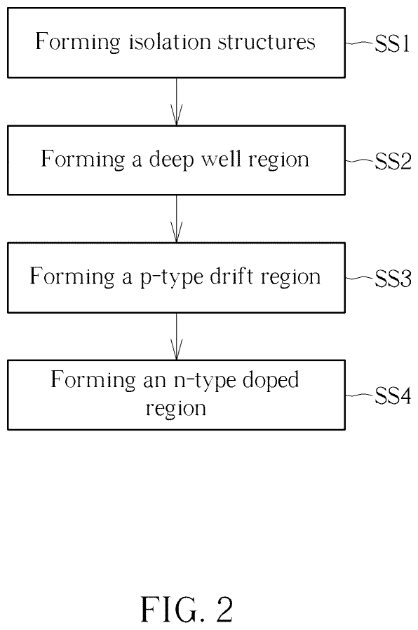

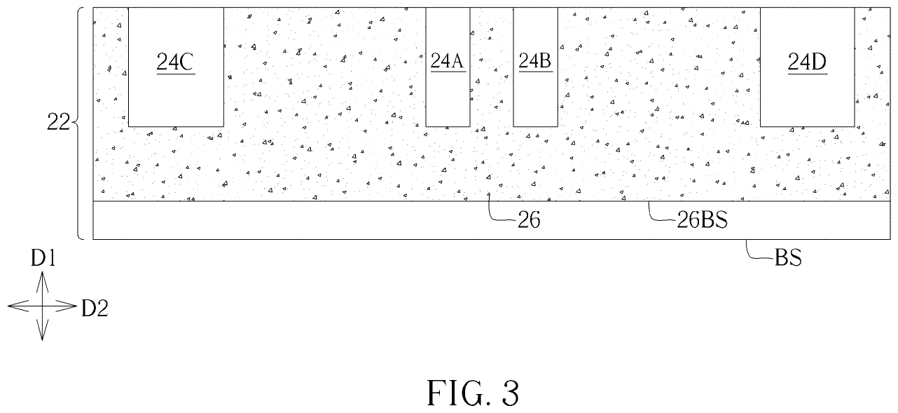

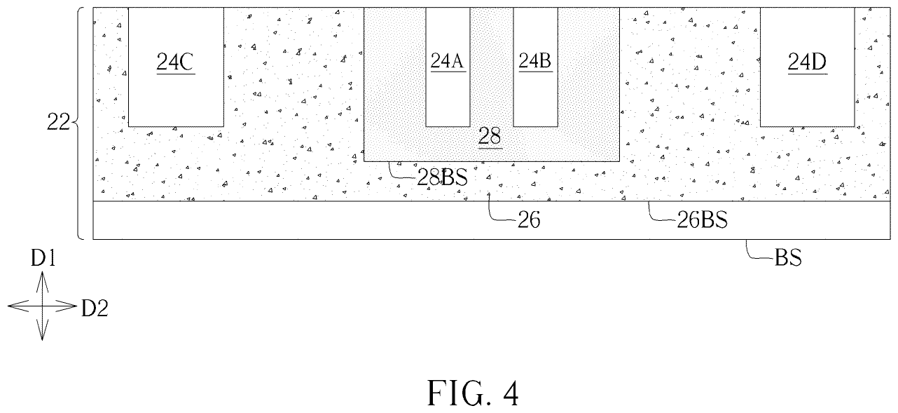

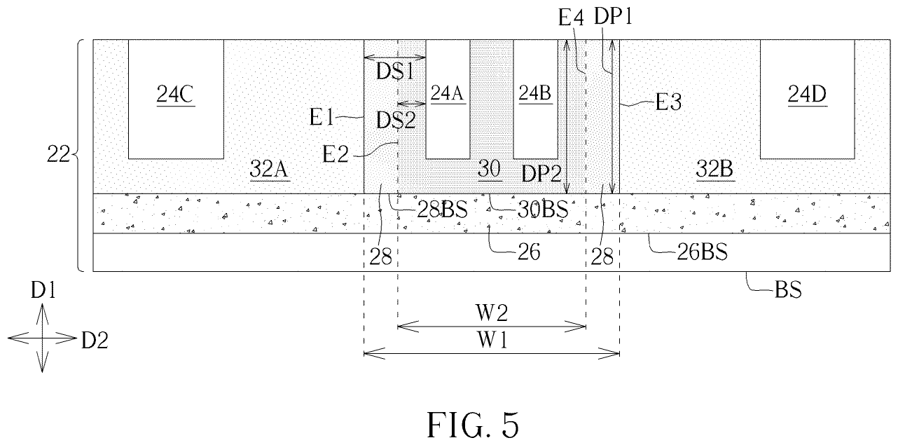

Please refer to FIG. 1 and FIGS. 2-5. FIG. 2 is a flow chart of a part of a manufacturing method of a high voltage semiconductor device according to an embodiment of the present invention. FIGS. 3-5 are schematic drawings illustrating a manufacturing method of a high voltage semiconductor device according to an embodiment of the present invention, wherein FIG. 4 is a schematic drawing in a step subsequent to FIG. 3, and FIG. 5 is a schematic drawing in a step subsequent to FIG. 4. In some embodiments, FIG. 1 may be regarded as a schematic drawing in a step subsequent to FIG. 5, but not limited thereto. As shown in FIG. 1, the manufacturing method in this embodiment may include the following steps. Firstly, the semiconductor substrate 22 is provided, and the isolation structure 24 is formed in the semiconductor substrate 22. The p-type drift region 28 is formed in the semiconductor substrate 22, and the n-type doped region 30 is formed in the p-type drift region 28. The bottom of the n-type doped region 30 (such as but not limited to the bottom surface 30BS) is directly connected with the bottom of the p-type drift region 28 (such as but not limited to the bottom surface 28BS). At least a part of the isolation structure 24A is disposed in the n-type doped region 30. The p-type drift region 28 includes a first lateral face (such as the lateral face E1), and the n-type doped region 30 includes a second lateral face (such as the lateral face E2) located between the lateral face E1 and the isolation structure 24A in the horizontal direction D2. The distance DS2 between the lateral face E2 and the isolation structure 24A in the horizontal direction D2 is less than the distance DS1 between the lateral face E1 and the isolation structure 24A in the horizontal direction D2.

Specifically, the manufacturing method in this embodiment may include but is not limited to the following steps. As shown in FIG. 2 and FIG. 3, a step SS1 may be carried out for forming isolation structures (such as the isolation structure 24A, the isolation structure 24B, the isolation structure 24C, and the isolation structure 24D), and a step SS2 may then be carried out for forming a deep well region (such as the deep n-type doped well region 26). Subsequently, as shown in FIG. 2 and FIG. 4, a step SS3 may be carried out for forming the p-type drift region 28, and the bottom surface 28BS of the p-type drift region 28 is higher than a bottom surface 26BS of the deep n-type doped well region 26 in the vertical direction D1. As shown in FIG. 2 and FIG. 5, a step SS4 may then be carried out for forming the n-type doped region 30, the n-typed doped well region 32A, and the n-type doped well region 32B. In some embodiments, the n-type doped region 30, the n-typed doped well region 32A, and the n-type doped well region 32B may be formed concurrently by the same process (such as an implantation process), and the n-type doped region 30, the n-typed doped well region 32A, and the n-type doped well region 32B may include the same n-type dopant accordingly. In addition, a thermal process may be carried out after the step SS4 for activating the doped regions described above, but not limited thereto. As shown in FIG. 5 and FIG. 1, after the n-type doped region 30, the n-typed doped well region 32A, and the n-type doped well region 32B are formed, the gate structure GS1, the gate structure GS2, the heavily p-type doped region 34, the heavily p-type doped region 36A, the heavily p-type doped region 36B, the heavily n-type doped region 38A, and the heavily n-type doped region 38B described above may be formed for forming the high voltage semiconductor device 101.

In some embodiments, the p-type drift region 28 and p-type doped regions in other area of the semiconductor substrate (such as a p-type doped well region in an input/output device region, but not limited thereto) may be formed concurrently by the same process, and the n-type doped region 30, the n-type doped well region 32A, the n-type doped well region 32B, and n-type doped regions in other area of the semiconductor substrate (such as an n-type doped well region in the input/output device region, but not limited thereto) may be formed concurrently by the same process for process simplification and/or manufacturing cost reduction, but not limited thereto. Therefore, the n-type doped region 30 is formed in the p-type drift region 28 and the range of the n-type doped region 30 is controlled for improving the electrical performance of the high voltage semiconductor device and reducing the negative influence on the reliability without increasing additional process steps and/or manufacturing cost.

The following description will detail the different embodiments of the present invention. To simplify the description, the following description will detail the dissimilarities among different embodiments and the identical features will not be redundantly described. In addition, identical components in each of the following embodiments are marked with identical symbols for making it easier to understand the differences between the embodiments.

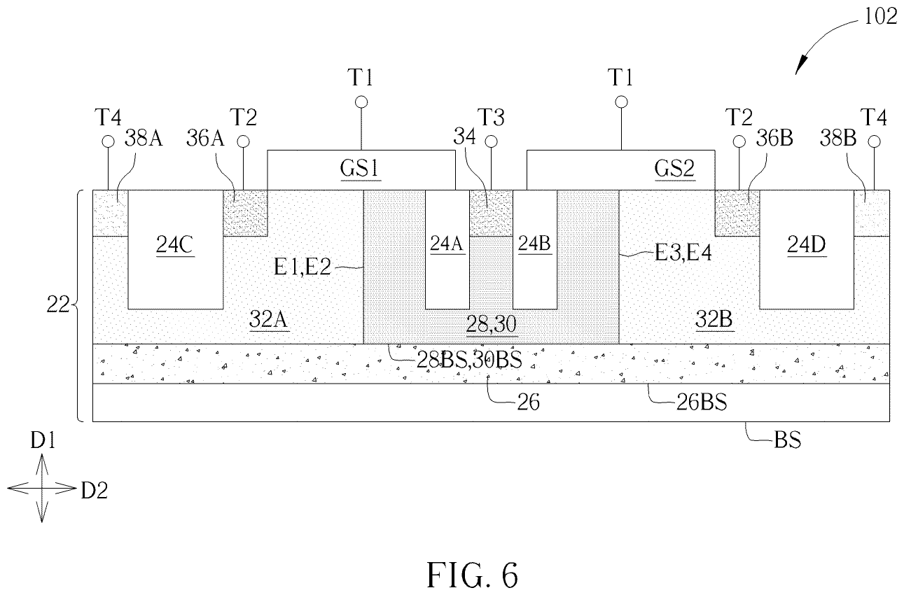

Please refer to FIG. 6. FIG. 6 is a schematic drawing illustrating a high voltage semiconductor device 102 according to a second embodiment of the present invention. As shown in FIG. 6, in the high voltage semiconductor device 102, the lateral face E2 and the lateral face E4 of the n-type doped region 30 may overlap and/or be flush with the lateral face E1 and the lateral face E3 of the p-type drift region 28, respectively, and the n-type doped region 30 may be formed in the whole p-type drift region 28. In the high voltage semiconductor device 102, the distance between the lateral face E2 and the isolation structure 24A in the horizontal direction D2 may be substantially equal to the distance between the lateral face E1 and the isolation structure 24A in the horizontal direction D2, and the distance between the lateral face E4 and the isolation structure 24B in the horizontal direction D2 may be substantially equal to the distance between the lateral face E3 and the isolation structure 24B in the horizontal direction D2.

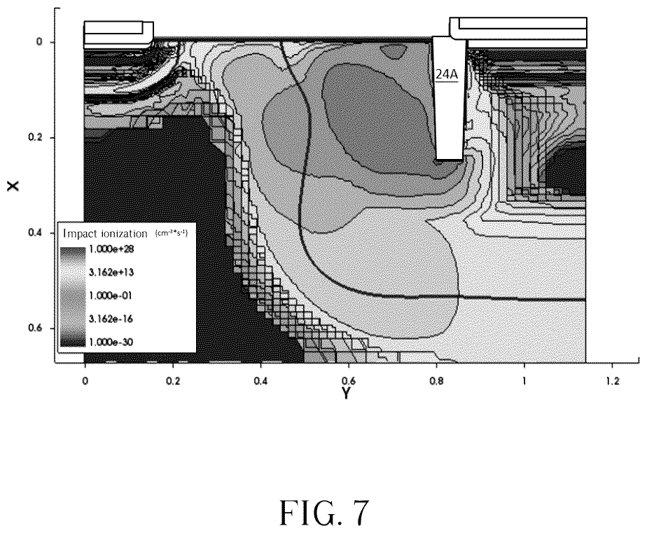

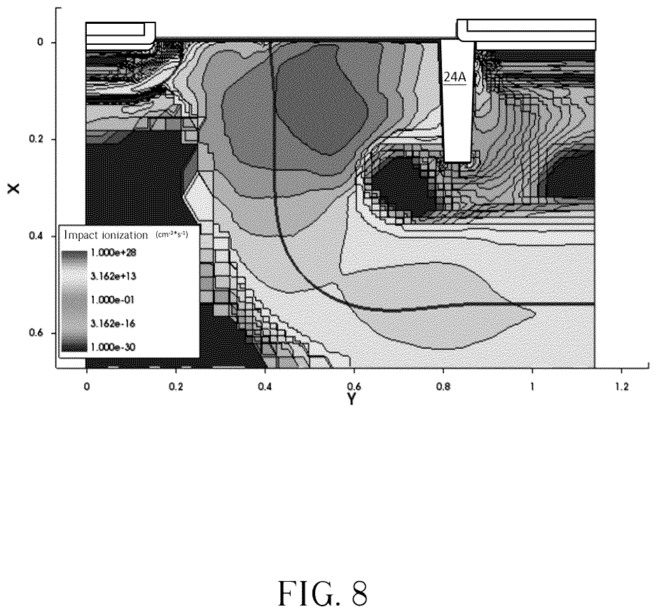

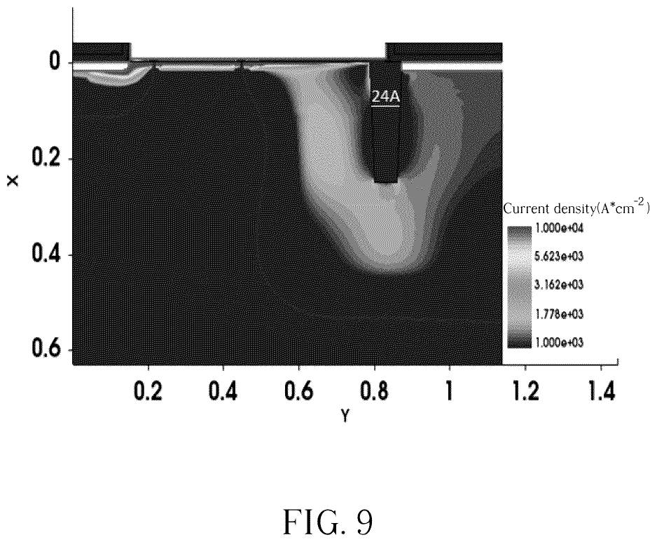

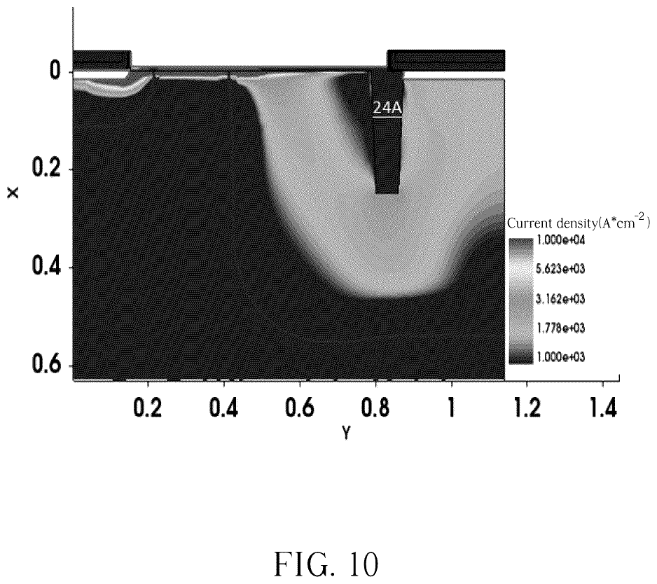

Please refer to FIG. 1 and FIGS. 6-10. FIG. 7 is a schematic drawing illustrating distribution of impact ionization in the high voltage semiconductor device according to the second embodiment of the present invention, FIG. 8 is a schematic drawing illustrating distribution of impact ionization in the high voltage semiconductor device according to the first embodiment of the present invention, FIG. 9 is a schematic drawing illustrating current distribution in the high voltage semiconductor device according to the second embodiment of the present invention, and FIG. 10 is a schematic drawing illustrating current distribution in the high voltage semiconductor device according to the first embodiment of the present invention. It is worth noting that, FIGS. 7-10 are schematic drawings illustrating the distribution within a portion of the corresponding high voltage semiconductor device during operation, the upper left parts in FIGS. 7-10 may be source regions (such as the region corresponding to the heavily p-type doped region 36A), and the upper right parts in FIGS. 7-10 may be drain regions (such as the region corresponding to the heavily p-type doped region 34), but not limited thereto. As shown in FIG. 1 and FIGS. 6-8, the range of the n-type doped region 30 in the high voltage semiconductor device 101 may be controlled and the width W2 of the n-type doped region 30 may be less than the width W1 of the p-type drift region 28 for adjusting the distribution of the impact ionization and/or the electric field distribution in the semiconductor substrate 22, and the impact ionization in the area under the isolation structure 24A and the area adjacent to the isolation structure 24A may be reduced especially. As shown in FIG. 1 and FIGS. 6-10, by controlling the range of the n-type doped region 30 in the high voltage semiconductor device 101 for adjusting the distribution of the impact ionization and/or the electric field distribution in the semiconductor substrate 22, the influence of the impact ionization on the current path may be reduced (for example, the current path in FIG. 10 may be relatively wide), and the reliability of the high voltage semiconductor device may be improved accordingly (for example, the hot carrier injection (HCl) test result may be improved, but not limited thereto).

To summarize the above descriptions, according to the high voltage semiconductor device and the manufacturing method in the present invention, the n-type doped region may be formed in the p-type drift region and the bottom of the n-type doped region may be directly connected with the bottom of the p-type drift region for improving the electrical performance of the high voltage semiconductor device (such as increasing the breakdown voltage, but not limited thereto), the location of the lateral face of the n-type doped region may be controlled for reducing the influence of the impact ionization on the current path, and the reliability may be improved accordingly. In addition, the n-type doped region, the n-type doped well region in the high voltage semiconductor device, and the n-type doped region in other area of the semiconductor substrate may be formed concurrently by the same process for process simplification and/or manufacturing cost reduction.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high voltage semiconductor device, comprising:
a semiconductor substrate;
a p-type drift region disposed in the semiconductor substrate;
an n-type doped region disposed in the p-type drift region, wherein a bottom of the n-type doped region is connected with a bottom of the p-type drift region; and
an isolation structure, wherein at least a part of the isolation structure is disposed in the n-type doped region, the p-type drift region comprises a first lateral face, the n-type doped region comprises a second lateral face located between the first lateral face and the isolation structure in a horizontal direction, and a distance between the second lateral face and the isolation structure in the horizontal direction is less than a distance between the first lateral face and the isolation structure in the horizontal direction.

2. The high voltage semiconductor device according to claim 1, wherein a bottom surface of the n-type doped region and a bottom surface of the p-type drift region are coplanar.

3. The high voltage semiconductor device according to claim 1, wherein a depth of the n-type doped region in a vertical direction is equal to a depth of the p-type drift region in the vertical direction.

4. The high voltage semiconductor device according to claim 1, wherein the distance between the second lateral face and the isolation structure in the horizontal direction is greater than or equal to 0.16 times the distance between the first lateral face and the isolation structure in the horizontal direction.

5. The high voltage semiconductor device according to claim 1, wherein the distance between the second lateral face and the isolation structure in the horizontal direction is less than or equal to 0.5 times the distance between the first lateral face and the isolation structure in the horizontal direction.

6. The high voltage semiconductor device according to claim 1, wherein the p-type drift region comprises p-type dopants, and the n-type doped region comprises n-type dopants and a part of the p-type dopants of the p-type drift region.

7. The high voltage semiconductor device according to claim 1, further comprising:
a gate structure disposed on the semiconductor substrate, wherein at least a part of the isolation structure is disposed under the gate structure in a vertical direction, and the first lateral face and the second lateral face are located under gate structure in the vertical direction.

8. The high voltage semiconductor device according to claim 7, further comprising:
a first heavily p-type doped region disposed in the p-type drift region, wherein the first heavily p-type doped region is located in the n-type doped region, and the second lateral face of the n-type doped region and the first heavily p-type doped region are located at two opposite sides of the isolation structure in the horizontal direction, respectively.

9. The high voltage semiconductor device according to claim 8, wherein a part of the n-type doped region and the first heavily p-type doped region are located at the two opposite sides of the isolation structure in the horizontal direction, respectively.

10. The high voltage semiconductor device according to claim 8, wherein the first lateral face of the p-type drift region and the first heavily p-type doped region are located at the two opposite sides of the isolation structure in the horizontal direction, respectively.

11. The high voltage semiconductor device according to claim 8, wherein a part of the p-type drift region and the first heavily p-type doped region are located at the two opposite sides of the isolation structure in the horizontal direction, respectively.

12. The high voltage semiconductor device according to claim 8, further comprising:
an n-type doped well region disposed in the semiconductor substrate, wherein a part of the n-type doped well region and a part of the p-type drift region are located at two opposite sides of the gate structure in the horizontal direction, respectively.

13. The high voltage semiconductor device according to claim 12, wherein the n-type doped region comprises first n-type dopants, the n-type doped well region comprises second n-type dopants, and each of the first n-type dopants is identical to each of the second n-type dopants.

14. The high voltage semiconductor device according to claim 12, further comprising:
a second heavily p-type doped region disposed in the n-type doped well region, wherein the first heavily p-type doped region and the second heavily p-type doped region are located at the two opposite sides of the gate structure in the horizontal direction, respectively.

15. The high voltage semiconductor device according to claim 14, wherein the first heavily p-type doped region is a drain doped region, and the second heavily p-type doped region is a source doped region.

16. The high voltage semiconductor device according to claim 1, further comprising:
a deep n-type doped well region disposed in the semiconductor substrate, wherein a part of the deep n-type doped well region is located under the p-type drift region and the n-type doped region in a vertical direction.

17. The high voltage semiconductor device according to claim 16, wherein a part of the n-type doped region is located between the isolation structure and the deep n-type doped well region in the vertical direction.

18. The high voltage semiconductor device according to claim 16, wherein the n-type doped region is directly connected with the deep n-type doped well region located under the n-type doped region in the vertical direction.

19. The high voltage semiconductor device according to claim 16, wherein the p-type drift region is directly connected with the deep n-type doped well region located under the p-type drift region in the vertical direction.

20. The high voltage semiconductor device according to claim 1, wherein a length of the n-type doped region in the horizontal direction is less than a length of the p-type drift region in the horizontal direction.
